(19) United States
(12) Patent Application Publication
(10) Pub. No.: US 2013/0130609 A1
(43) Pub. Date: May 23, 2013

(54) FAN CONTROL SYSTEM AND METHOD THEREOF

(71) Applicant: Chia-Hsiang Chen, Taipei City (TW)

(72) Inventor: Chia-Hsiang Chen, Taipei City (TW)

(73) Assignee: INVENTEC CORPORATION, Taipei City (TW)

(21) Appl. No.: 13/337,785

(22) Filed: Dec. 27, 2011

(30) Foreign Application Priority Data
Nov. 22, 2011 (TW) 100142636

(51) Int. Cl. F24F 11/04; F24F 11/053; H05K 5/02; F24F 7/007

(52) U.S. Cl. 454/184; 454/338; 454/256

(57) ABSTRACT

A fan control system and a method thereof are provided. The fan control system is suited for a plurality of racks placed in an accommodation space. The fan control system includes a plurality of fan units and a fan control device. Each of the fan units is respectively disposed on each of the racks, and the fan units are arranged according to at least one air flow direction. The fan control device drives the fan units according to a driving sequence. In other words, the fan control device circularly and sequentially drives the fan units according to an order of the fan units. Thus, the fan control system maintains movement of air flow without driving all the fan units at the same time, so that the racks placed in the accommodation space are cooled efficiently and the required electric power is reduced.

### CROSS-REFERENCE TO RELATED APPLICATION

This application claims the priority benefit of Taiwan application serial no. 100142636, filed Nov. 22, 2011. The entirety of the above-mentioned patent application is hereby incorporated by reference herein and made a part of this specification.

### BACKGROUND OF THE INVENTION

1. Field of the Invention

The present invention relates to heat-dissipation technologies, in particular, to a fan control system and a method thereof.

2. Description of Related Art

In the field of network service and information transmission, multiple manufacturers set multiple servers according to remote services provided by the manufacturers or service demands. However, construction and maintenance of network devices are rather expensive. In order to reduce the operation cost, the manufacturers desire to integrate the servers into a data center for centralized management.

When the data center needs to be constructed in the past, a machine room with a large accommodation space is required, and the data center begins to be constructed after an overall design of a heat-dissipation system and circuitry. Therefore, the construction takes too much time and the design is complicated. In the current data center construction, the heat-dissipation system, the circuitry design and numerous racks of the servers are designed and constructed in a container in advance. Then, the containers disposed with the servers are placed in a plant through transporting, and lines (for example, high-voltage lines and information transmission lines) required by the containers are connected, so that the multiple servers in the container operate to simplify the construction time course of the data center. Therefore, the container disposed with multiple servers may be referred to as a container computer.

Due to the widespread application of cloud technologies, multiple manufacturers invest in the design, manufacturing and production of the container computer currently. In the container computer, multiple heat-dissipation systems (for example, an air conditioning system, a water-cooled heat-dissipation system and a fan-type heat-dissipation system) are integrated for use, so that multiple servers can maintain operating in certain operating temperature through the function of the heat-dissipation system, thus achieving an effect of properly using the electric power. Since the container has an accommodation space with a certain capacity, most of the current container computers usually use the air conditioning system as the main heat-dissipation measure. However, the air conditioning system consumes the highest electric quantity in the multiple heat-dissipation systems, which may waste excessive electric power. Therefore, in the development and research field of the data center, how to integrate the heat-dissipation systems of the container computer with the consideration of the electric power consumption is one of the issues to be solved.

### SUMMARY OF THE INVENTION

Accordingly, the present invention is directed to a fan control system and a method thereof. In the embodiments of the present invention, the movement of the air flow can be maintained without driving all the fan units at the same time, so that racks can be cooled efficiently and the required electric power is reduced at the same time.

The present invention provides a fan control system, which is suited for a plurality of racks placed in an accommodation space (for example, a container). The heat-dissipation system includes a plurality of fan units and a fan control device. Each of the fan units is configured on the corresponding rack, and the fan units are arranged according to an air flow direction. The fan control device drives the fan units according to a driving sequence.

In an embodiment of the present invention, the driving sequence may be that, the fan control device sequentially and circularly drives the fan units according to the order of the fan units.

In an embodiment of the present invention, the fan control device drives a specific fan unit in a driving period, and stops driving the specific fan unit in an interruption period. The specific fan unit is one of the fan units, and each of the fan units corresponds to a different driving period.

In an embodiment of the present invention, the fan unit is a fan wall, and the accommodation space is determined by the container.

In an embodiment of the present invention, the rack includes a plurality of server units, and the fan control device is one of the server units.

In an embodiment of the present invention, when detecting that temperature information of one of the racks (for example, a specific rack) exceeds a preset temperature range, the fan control device continuously drives the fan unit configured on the specific rack and drives the remaining fan units according to the driving sequence. On the other hand, when detecting that the temperature information of one of the racks (for example, a specific rack) is always below the preset temperature range, the fan control device may stop driving the fan unit configured on the specific rack and drives the remaining fan units according to the driving sequence.

From another point of view, the present invention provides a fan control method that is suited for a plurality of racks placed in an accommodation space, where the racks are configured with a plurality of fan units respectively. The fan control method includes the following steps: arranging the fan units according to an air flow direction, and driving the fan units according to a driving sequence.

In an embodiment of the present invention, the driving the fan units according to the driving sequence includes: sequentially and circularly driving the fan units according to an order of the fan units.

In an embodiment of the present invention, the driving the fan units according to the driving sequence includes: driving a specific fan unit in a driving period, and stopping driving the specific fan unit in an interruption period. The specific fan unit is one of the fan units, and each of the fan units corresponds to a different driving period.

On the basis of the above description, in the embodiments of the present invention, the racks and fan units located in the accommodation space are arranged according to a specific air flow direction. Therefore, the fan control device sequentially and circularly drives the fan units according to the order, so that the fan units maintain the movement of the air flow through physical inertia, so as to save the electric power. Therefore, in the embodiments of the present invention, the electric power consumed due to the driving of the fan units in the interruption period can be saved without driving all the fan units at the same time; meanwhile, the movement of the air flow is maintained.

In order to make the features and advantages of the present invention more comprehensible, the present invention is described in detail in the following with reference to the embodiments and the accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a container computer according to a first embodiment of the present invention.

FIG. 2 is a schematic view of a rack and a fan unit in FIG. 1.

FIG. 3 is a schematic view of a fan control system according to the first embodiment of the present invention.

FIG. 4 is a flow chart of a fan control method according to the first embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

To make a container (or referred to as a container computer) disposed with multiple servers maintains operating in a certain operating temperature, it hopes that a heat-dissipation system disposed in the container computer consumes few electric power to control the temperature in the above case. Therefore, the spirit of the embodiments of the present invention lies in that, racks and configured fan units are arranged according to a preset air flow direction, and the fan units are sequentially and circularly driven, so as to use physical inertia of the fan blades to save the electric power, and continuously maintain unimpeded movement of the air flow. In view of the above, the present invention provides the following embodiments to implement the present invention.

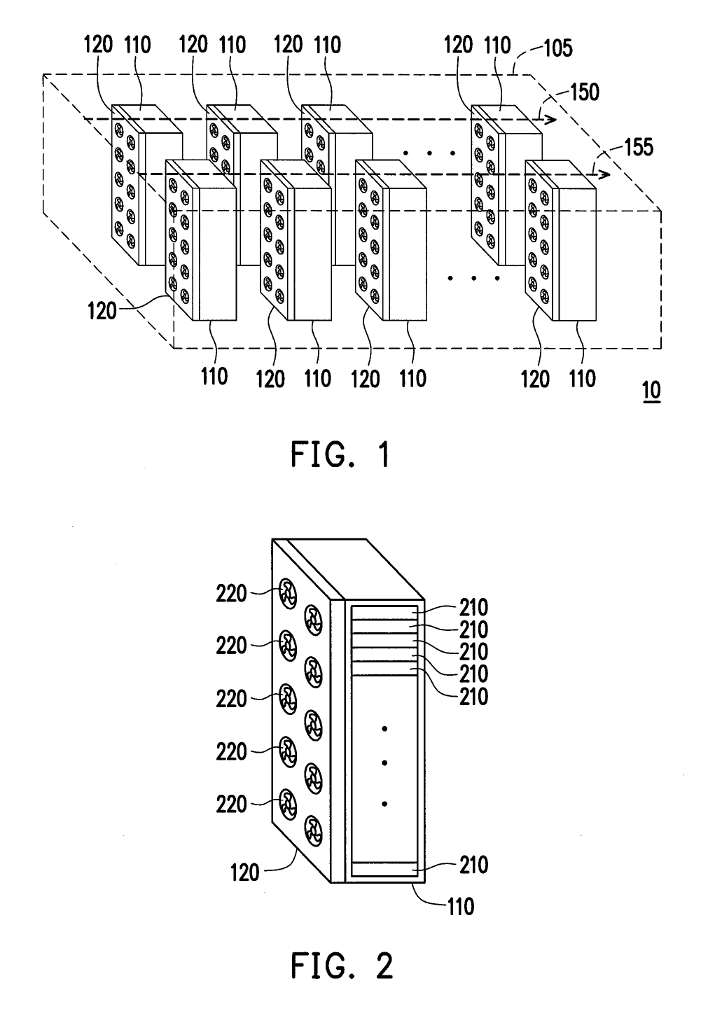

Referring to FIG. 1, a schematic view of a container computer 10 according to a first embodiment of the present invention is shown. As shown in FIG. 1, the container computer 10 is in a shape of a container 105, and an accommodation space of the container 105 may be adjusted by a user applying this embodiment, or is determined according to a capacity type designated for the current container. The accommodation space in the container computer 10 includes a plurality of racks 110, and each of the racks 110 is configured with a fan unit 120 respectively. The racks 110 may be racks 110 of the same type for ease of management, or may be racks 110 of different structural shapes or different types according to requirements of the user.

The structure of the rack 110 and the fan unit 120 is described herein, and FIG. 2 is a schematic view of the rack 110 and the fan unit 120 in FIG. 1. As shown in FIG. 2, in this embodiment, the rack 110 may be disposed with a plurality of servers 210 (that is, an entity machine), and the servers 210 may be blade servers. In this embodiment, each of the blade servers may include one or more entity servers, which is determined according to the requirements of the user applying this embodiment. The fan unit 120 may be a fan wall. In other words, the fan unit 120 consists of a plurality of fans 220, the fans 220 are unifiedly driven by the power source, and blades of the fans 220 drive the air to form an air flow. The air flow here may be referred to as a wind current.

Therefore, heat energy generated due to the operation of the multiple servers 210 in the rack 110 can be removed from the servers 210 by the wind current, thus reducing the operating temperature of the servers 210. In this embodiment, each rack 110 may include a water-cooled heat-dissipation system, so that the servers 210 can use the fan control system and the water-cooled heat-dissipation system described in the present invention to achieve a bi-cooling effect. It should be noted that, referring to FIG. 1, the racks 110 and the configured fan units 120 are arranged according to at least one air flow direction 150 or 155 in the embodiment of the present invention. Therefore, the fan units 120 in FIG. 1 are sequentially arranged by facing the air flow directions 150 and 155.

In addition, in other embodiments, the air flow directions 150 and 155 in FIG. 1 may be a direction from one side of the container to the other side, and moreover, the air flow direction 155 may indicate in contradiction, so that the air flow of the racks 110 forms a rectangle circulation. Alternatively, the racks 110 enclose a circle to form a circular air flow direction. On the basis of the above description, it can be understood that, the air flow direction in the embodiment of the present invention should not be limited to the air flow directions 150 and 155 in FIG. 1, and this embodiment does not limit the shape and direction of the air flow direction.

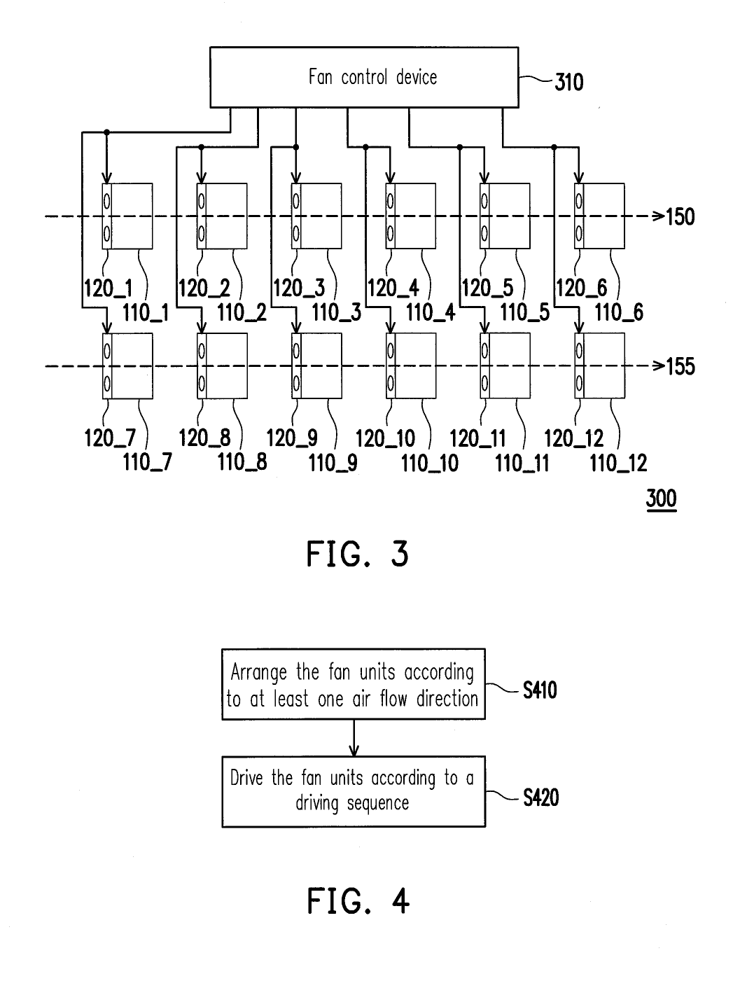

In this embodiment, each rack 110 has one or more network exchanges on a top of the rack, so that the servers 210 in each rack 110 may be connected to each other through the network (for example, an internet protocol), and communicate with the outside through lines connected to the outside of the container 105. Therefore, a fan control system 300 described in the embodiment of the present invention may be implemented according to the container computer 10 of FIG. 1. FIG. 3 is a schematic view of a fan control system 300 according to the first embodiment of the present invention. For ease of describing, the container computer 10 of this embodiment includes 12 racks 110_1-110_12; however, the number of the racks does not limit the present invention.

Referring to FIG. 3, the fan control system 300 includes a plurality of fan units 120_1-120_12, and a fan control device 310. Each of the fan units 120_1-120_12 is configured on the corresponding rack 110_1-110_12, and the fan units 120_1-120_12 are arranged according to an air flow direction 150. The view of the racks 110_1-110_12 and the fan units 120_1-120_12 shown herein is a schematic skeleton diagram obtained through the observation from an upper direction of the container 105. In addition, in this embodiment, the fan control device 310 may be located in one of the servers in the racks 110_1-110_12, so as to control/drive the fan units 120_1-120_12 according to a driving sequence. In other embodiments, the fan control device 310 may also be independently disposed on a specific device in the container computer, and is not necessarily located in one server in the racks 110_1-110_12, so the present invention is not limited thereto.

To specify the embodiment of the present invention, the fan units 120_1-120_6 located in the same air flow direction 150 are taken as an example to illustrate the driving sequence described in the embodiment of the present invention. Table (1) is a schematic table of a driving sequence of the fan control device 310 for the fan units 120_1-120_6.

TABLE 1

| Driving | | | | | | |
|---|---|---|---|---|---|---|
| tags of the | T1 | T2 | T3 | T4 | T5 | T6 |
| fan units | (120_1) | (120_2) | (120_3) | (120_4) | (120_5) | (120_6) |
| Driving | 1 | 0 | 0 | 0 | 0 | 0 |
| sequence | 0 | 1 | 0 | 0 | 0 | 0 |
| | 0 | 0 | 1 | 0 | 0 | 0 |
| | 0 | 0 | 0 | 1 | 0 | 0 |
| | 0 | 0 | 0 | 0 | 1 | 0 |
| | 0 | 0 | 0 | 0 | 0 | 1 |
| | 1 | 0 | 0 | 0 | 0 | 0 |
| | 0 | 1 | 0 | 0 | 0 | 0 |
| | 0 | 0 | 1 | 0 | 0 | 0 |

In table (1), the row indicates driving tags T1-T6 corresponding to the fan units 120_1-120_6, so as to use the driving tags T1-T6 to indicate a driving condition of the fan units 120_1-120_6. When the driving tags T1-T6 are “1”, it indicates that the fan control device 310 is driving the fan unit. In other words, the fan control device 310 supplies power to the fan unit at this time to increase the rotation speed of the fan unit, or maintains the blades of the fan unit at a certain rotation speed. On the other hand, when the driving tags T1-T6 are “0”, it indicates that the fan control device 310 stops driving the fan unit. In other words, the fan control device 310 stops supplying power to the fan unit at this time. The driving sequence of the fan control device 310 successively descends from the driving tags T1-T6 in the uppermost row for execution.

Referring to FIG. 3 and table (1), the driving sequence described in this embodiment may be that, the fan control device 310 sequentially and circularly drives the fan units 120_1-120_6 according to an order of the fan units (for example, the fan units 120_1-120_6). In this embodiment, the fan control device 310 may taken polling driving and power supply as an example to describe the driving sequence.

For example, it can be known from table (1) that, when a temperature sensor on each of the racks 110_1-110_6 senses the temperature information of the racks 110_1-110_6 and the temperature does not exceed a temperature range, that is, each of the racks 110_1-110_6 does not send an overheating signal to the fan control device 310 due to the overheating, the fan control device 310 drives a fan unit each time (for example, a specific fan unit 120_1) and stops driving the remaining fan units (for example, the fan units 1202-120_6) at the same time, that is, the fan control device 310 stops supplying power to the fan units 1202-120_6, which is the same as an implication indicated by the driving tags T1-T6 in the first row of table (1). In other word, the fan unit 120_1 is in a driving period, and the fan units 120_2-120_6 are in an interruption period at this time.

Afterwards, as an implication indicated by the driving tags T1-T6 in the second row of table (1), after a driving period t1, the fan control device 310 drives the fan unit 1202, and stops driving the remaining fan units 120_1 and 120_3-120_6 at the same time. In other words, the fan units 120_1 and 120_3-120_6 are in an interruption period at this time, and the fan unit 120_2 is in a driving period.

Therefore, since each of the fan units 120_1-120_6 is driven by the power supply in the driving period, the blades of the fan units 120_1-120_6 maintain in a certain rotation speed. Moreover, during the interruption period of each of the fan units 120_1-120_6, since the blades of the fan units 120_1-120_6 maintain rotating due to physical inertia, the fan units do not stop at once due to short power off, thus maintaining a characteristic of conducted air flow. In view of this, in the embodiment of the present invention, it is not required to drive all the fan units 120_1-120_6 at the same time. In this way, electric power consumed due to the driving of the fan units 120_1-120_6 in the interruption period can be saved, thus achieving a same heat-dissipation effect. It can be known that, the fan units (for example, the fan units 120_1-120_6) in the same air flow direction (for example, the air flow direction 150) should correspond to different driving periods.

It should be noted that, in other embodiments, the fan control device 310 may also drive multiple fan units at the same time (for example, driving the fan units 120_1-120_2 at the same time) and stops driving other fan units (for example, stops driving the fan units 120_3-120_6). In this way, the spirit described in the embodiments of the present invention may also be achieved, and the electric power consumed due to the driving of the fan units 120_3-120_6 in the interruption period can be saved. Therefore, the user applying this embodiment may determine the number of the fan units to be driven at the same time according to the requirements.

In addition, in other implementation details of the embodiment of the present invention, each of the racks 110_1-110_6 is disposed with a temperature sensor all around or on a specific position, and one master server in each of the racks 110_1-110_6 integrates the information sensed by the temperature sensor of the rack and then delivers the information to the fan control device 310 after the integration, so that the fan control device 310 knows a temperature condition of an area where each of the racks 110_1-110_6 is located.

Table (2) is another schematic table of a driving sequence of the fan control device 310 for the fan units 120_1-120_6.

TABLE 2

| Driving | | | | | | |
|---|---|---|---|---|---|---|
| tags of the | T1 | T2 | T3 | T4 | T5 | T6 |
| fan units | (120_1) | (120_2) | (120_3) | (120_4) | (120_5) | (120_6) |
| 0 | 1 | 0 | 0 | 1 | 0 | 0 |
| | 0 | 1 | 0 | 1 | 0 | 0 |
| | 0 | 0 | 1 | 1 | 0 | 0 |
| | 0 | 0 | 0 | 1 | 1 | 0 |
| | 0 | 0 | 0 | 1 | 0 | 1 |
| | 1 | 0 | 0 | 1 | 0 | 0 |
| | 0 | 1 | 0 | 1 | 0 | 0 |
| | 0 | 0 | 1 | 1 | 0 | 0 |
| | 0 | 0 | 0 | 1 | 1 | 0 |

Referring to FIG. 3 and table (2), if the temperature of the rack 110_4 always exceeds the preset temperature range due to an environmental factor, is indicates that the rack 110_4 needs to be fast cooled to avoid breakdown of the server in the rack 110_4 due to overheating. Therefore, when the fan control device 310 detects that the temperature information of one of the racks (for example, the rack 110_4) exceeds the preset temperature range, the fan control device 310 continuously drive the fan unit 120_4 correspondingly configured on the rack 110_4. That is to say, the fan control device 310 sets the driving tag T4 of the fan unit 120_4 to “1”, and drives the remaining fan units 120_1-120_3 and 120_5-120_6 other than the fan unit 120_4 according to the polling driving sequence, so that the rack 110_4 can be fast cooled, and the remaining fan units 120_1-120_3 and 120_5-120_6 can save the electric power and achieve the same heat-dissipation effect according to the embodiment of the present invention.

In addition, comparatively, table (3) is another schematic table of a driving sequence of the fan control device 310 for the fan units 120_1-120_6.

TABLE 3

| Driving | | | | | | |
|---|---|---|---|---|---|---|
| tags of the | T1 | T2 | T3 | T4 | T5 | T6 |
| fan units | (120_1) | (120_2) | (120_3) | (120_4) | (120_5) | (120_6) |
| 0 | 1 | 0 | 0 | 0 | 0 | 0 |
| | 0 | 1 | 0 | 0 | 0 | 0 |
| | 0 | 0 | 1 | 0 | 0 | 0 |
| | 0 | 0 | 0 | 0 | 1 | 0 |
| | 0 | 0 | 0 | 0 | 0 | 1 |
| | 1 | 0 | 0 | 0 | 0 | 0 |
| | 0 | 1 | 0 | 0 | 0 | 0 |
| | 0 | 0 | 1 | 0 | 0 | 0 |
| | 0 | 0 | 0 | 0 | 1 | 0 |

Referring to FIG. 3 and table (3), if the temperature of the rack 110_4 never exceeds the preset temperature range due to the environmental factor but is far below the preset temperature range, it indicates that the fan control device 310 may stop driving the fan wall of the rack to save the electric power. Therefore, when the fan control device 310 detects that the temperature information of one of the racks (for example, the rack 110_4) is below the preset temperature range, the fan control device 310 may continuously stop driving the fan unit 120_4 correspondingly configured on the rack 110_4 to save the electric power. That is to say, the fan control device 310 sets the driving tag T4 of the fan unit 120_4 to “0” and drives the remaining fan units 120_1-120_3 and 120_5-120_6 other than the fan unit 120_4 according to the polling driving sequence, so as to further save the required electric power.

From another point of view, the present invention also provides a fan control method, and FIG. 4 is a flow chart of a fan control method according to the first embodiment of the present invention. The fan control method may be suited for a plurality of racks placed in an accommodation space (for example, a container), and each of the racks is configured with a fan unit (for example, a fan wall). In the fan control method, first, in step S410, the fan units are arranged according to at least one air flow direction; and in step S420, the fan units are driven according to a driving sequence. In addition, other detailed procedures of this embodiment are included in the above embodiments, which are not described herein again.

To sum up, in the embodiments of the present invention, the racks and the fan units located in the accommodation space are arranged according to a specific air flow direction. Therefore, the fan control device sequentially and circularly drives the fan units according to the order, so that the fan units maintain the movement of the air flow to save the electric energy to be consumed.

In other words, each fan unit may be driven in the driving period, so that a rotation speed of the blades of the fan unit is increased, or the fans are maintained at a certain high rotation speed. In addition, in the interruption period, since the blades of the fan units maintain rotating due to physical inertia, and low friction is imposed on the fan units, the fan units do not stop at once due to short power off and maintain a characteristic of conducted air flow before the next driving period comes. Therefore, in the embodiments of the present invention, and the electric power consumed due to the driving of the fan units in the interruption period can be saved without driving all the fan units; meanwhile, the movement of the air flow is maintained.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fan control system, suited for a plurality of racks placed in an accommodation space, and the heat-dissipation system comprising:
a plurality of fan units, wherein each of the fan units is configured on each rack, and the fan units are arranged according to at least one air flow direction; and
a fan control device, driving the fan units according to a driving sequence.

2. The fan control system according to claim 1, wherein the driving sequence is that, the fan control device sequentially and circularly drives the fan units according to an order of the fan units.

3. The fan control system according to claim 1, wherein the fan control device drives a specific fan unit in a driving period and stops driving the specific fan unit in an interruption period, the specific fan unit is one of the fan units, and each of the fan units corresponds to a different driving period.

4. The fan control system according to claim 1, wherein each of the fan units is a fan wall, and the accommodation space is determined by a container.

5. The fan control system according to claim 1, wherein the racks comprise a plurality of server units, and the fan control device is one of the server units.

6. The fan control system according to claim 1, wherein when detecting that temperature information of a specific rack exceeds a preset temperature range, the fan control device continuously drives a specific fan unit configured on the specific rack and drives the remaining fan units according to the driving sequence, and the specific rack is one of the racks.

7. The fan control system according to claim 1, wherein when detecting that temperature information of a specific rack is below a preset temperature range, the fan control device stops driving a specific fan unit configured on the specific rack and drives the remaining fan units according to the driving sequence.

8. A fan control method, suited for a plurality of racks placed in an accommodation space, wherein the racks are configured with a plurality of fan units, and the fan control method comprising:
arranging the fan units according to at least one air flow direction; and
driving the fan units according to a driving sequence.

9. The fan control method according to claim 8, wherein the driving the fan units according to the driving sequence comprises:
sequentially and circularly driving the fan units according to an order of the fan units.

10. The fan control method according to claim 8, wherein the driving the fan units according to a driving sequence comprises:
driving a specific fan unit in a driving period; and
stopping driving the specific fan unit in an interruption period, wherein the specific fan unit is one of the fan units, and each fan unit corresponds to a different driving period.
